(19) United States
(12) Patent Application Publication
(10) Pub. No.: US 2011/0248757 A1
(43) Pub. Date: Oct. 13, 2011

(54) DIGITAL CALIBRATION DEVICE AND METHOD FOR HIGH SPEED DIGITAL SYSTEMS

(76) Inventors: SAKET JALAN, Bangalore (IN); Raghu Ganesan, Bangalore (IN); Jawaharlal Tangudu, Bangalore (IN)

(21) Appl. No.: 12/756,187

(22) Filed: Apr. 8, 2010

(51) Int. Cl. H03L 7/00

(52) U.S. Cl. 327/161

(57) ABSTRACT

A digital calibration device and method for a high speed digital system. A digital calibration device coupled to a timing device in a high speed digital system for digitally calibrating the timing device includes a delay estimator, a control logic, and a digitally controlled load unit. In operation, the delay estimator calculates a delay value indicative of a timing delay between a first output and a second output of a timing device of the high speed digital system. Further, the control logic generates a control signal based on the delay value. Furthermore, the digitally controlled load unit applies at least one of a first load to a non-delayed line and a second load to a delayed line of the timing device based on the control signal to calibrate a timing delay between the non-delayed line and the delayed line of the timing device.

### TECHNICAL FIELD

Embodiments of the disclosure generally relate to the field of electronics, and more particularly to a digital calibration device and method.

### BACKGROUND

In high speed digital systems, timing of signals can be important to the operation of such systems. For example, inconsistencies in outputs of timing devices used in the high speed digital systems can cause malfunctions. Timing devices such as phase locked loops (PLLs), all digital phase locked loops (ADPLLs), and time-to-digital converters (TDCs) are used in many high speed digital systems. The ADPLLs, for instance, are an integral part of frequency control in radio frequency (RF) circuits for mobile applications and communication circuits. Further, TDCs can be used in other circuits to correct errors in time delay. For example, the TDC may convert a timing delay that occurs between timing of a first input signal and timing of a second input signal into a digital value.

A vernier delay line circuit is often used in a TDC to achieve a higher time resolution when compared to conventional TDCs. A half vernier delay line circuit used with a TDC achieves even greater time resolution. Vernier delay line TDCs, as with other timing devices, may require analog components and may also need extensive matching and design time. Further, measurement accuracy of the timing devices may depend on the matching of delay elements between successive stages. While layout design may help in minimizing mismatches, it may fail to eliminate the mismatches completely due to fluctuations in the process, temperature, or voltage.

### SUMMARY

This summary is provided to comply with 37 C.F.R. §1.73, requiring a summary of the invention briefly indicating the nature and substance of the invention. It is submitted with the understanding that it will not be used to interpret or limit the scope or meaning of the claims.

A digital calibration device and method for a high speed digital system are disclosed. In one aspect, a digital calibration device for a high speed digital system includes a delay estimator for calculating a delay value indicative of a timing delay between a first output and a second output of a timing device of the high speed digital system. The digital calibration device also includes control logic for generating a control signal based on the delay value. The digital calibration device further includes a digitally controlled load unit for applying at least one of a first load to a non-delayed line and a second load to a delayed line of the timing device based on the control signal to calibrate a timing delay between the non-delayed line and the delayed line of the timing device.

In another aspect, in a method for a digital calibration device to calibrate a timing device in a high speed digital system, a delay value indicative of a timing delay between a first output and a second output of the timing device of the high speed digital system is calculated. A control signal is then generated based on the delay value. Further, at least one of a first load to a non-delayed line and a second load to a delayed line of the timing device is applied based on the control signal to calibrate a timing delay between the non-delayed line and the delayed line of the timing device.

In yet another aspect, a wireless device includes a high speed digital system which further includes a timing circuit for receiving a first input signal and a second input signal and for providing a first output and a second output. The high speed digital system also includes a digital calibration circuit coupled to the timing circuit, where the digital calibration circuit further includes a delay estimator for calculating a delay value indicative of a timing delay between the first output and the second output of the timing circuit, a control logic for generating a control signal based on the delay value, and a digitally controlled load unit for applying at least one of a first load to a non-delayed line and a second load to a delayed line of the timing circuit based on the control signal to calibrate a timing delay between the non-delayed line and the delayed line of the timing circuit.

Other features of the embodiments will be apparent from the accompanying drawings and from the detailed description that follows.

### BRIEF DESCRIPTION OF THE VIEWS OF DRAWINGS

FIG. 1 illustrates a block diagram of a high speed digital system implementing a digital calibration device, according to one embodiment.

FIG. 2 illustrates a circuit diagram of the high speed digital system implementing the digital calibration device with a half vernier time-to-digital converter (TDC), according to one embodiment.

FIG. 3 illustrates a circuit diagram of the delay estimator of the digital calibration device of FIG. 2.

FIG. 4 illustrates a process flow chart of an exemplary method of a digital calibration device for digitally calibrating a timing device in a high speed digital system, according to one embodiment.

FIG. 5 illustrates an exemplary implementation of the high speed digital system of FIG. 1 in a wireless device.

### DETAILED DESCRIPTION

A digital calibration device and method for a high speed digital system are disclosed. The following description is merely exemplary in nature and is not intended to limit the present disclosure, applications, or uses. It should be understood that throughout the drawings, corresponding reference numerals indicate like or corresponding parts and features.

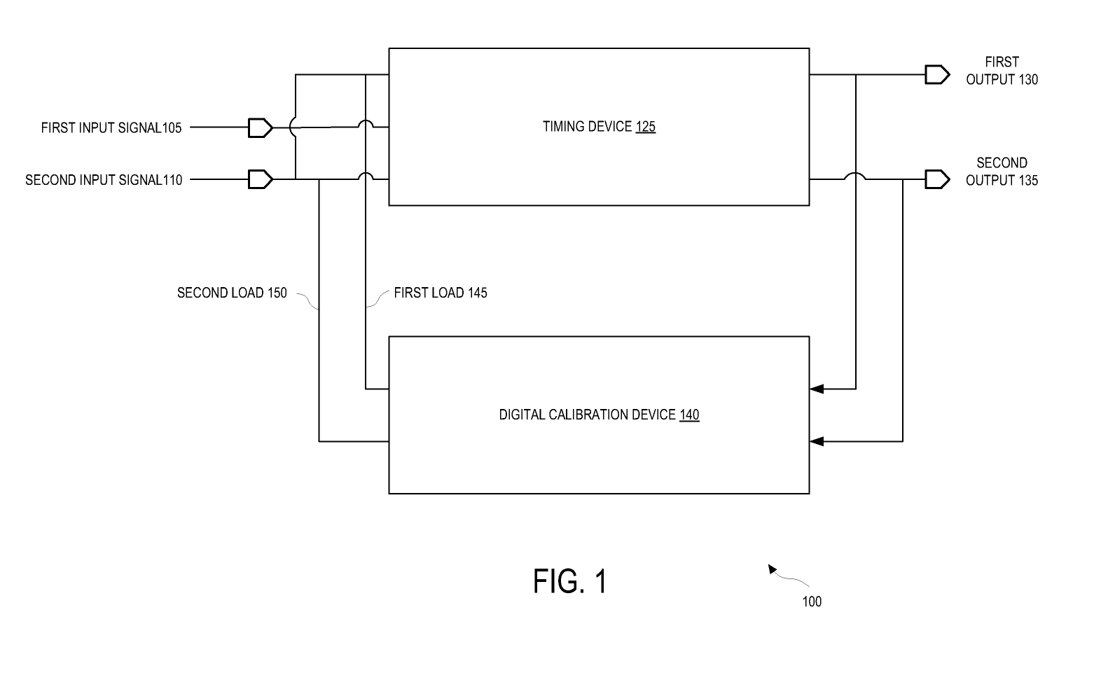

FIG. 1 illustrates a block diagram of a high speed digital system 100 implementing a digital calibration device 140, according to one embodiment. The high speed digital system 100 includes a timing device 125 and the digital calibration device 140. The timing device 125 receives a first input signal 105 and a second input signal 110, with the timing device 125 receiving the second input signal 110 using two input lines. The timing device 125 produces a first output 130 and a second output 135, where a timing delay may exist between the first output 130 and the second output 135. The timing delay can be defined as a delay in terms of time, phase, or any other measure. The digital calibration device 140 receives the first output 130 and the second output 135. The outputs of the digital calibration device 140 apply a first load 145 to one input line receiving the second input signal 110 and apply a second load 150 to the other input line receiving the second input signal 110.

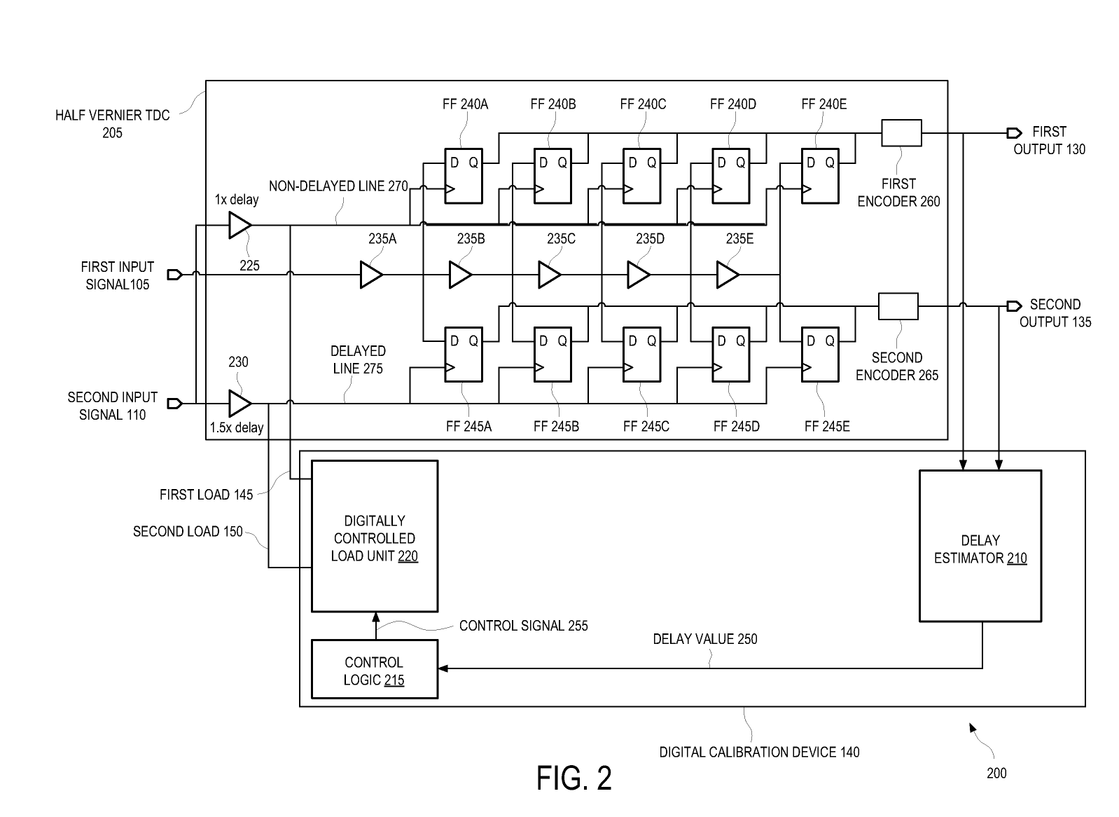

In an exemplary operation, the digital calibration device 140 calculates a delay value indicative of a timing delay between the first output 130 and a second output 135 of the timing device 125. Further, the digital calibration device 140 generates a control signal based on the calculated delay value, and then applies the first load 145 and the second load 150 to a non-delayed line (e.g., the non-delayed line 270 of FIG. 2) and a delayed line (e.g., the delayed line 275 of FIG. 2) of the timing device 125 based on the control signal to calibrate a timing delay between the delayed line and the non-delayed line. It is appreciated that the high speed digital system 100 can be systems including, but not limited to, integrated circuits, microprocessors, digital signal processors and digital radio frequency (RF) processors. It is also appreciated that the timing device 125 can be any number of devices including, but not limited to, timing circuits such as time-to-digital converters (TDC), vernier TDCs, half vernier TDCs, phase locked loop circuits (PLL) and all digital phase locked loop circuits (ADPLL).

FIG. 2 illustrates a circuit diagram 200 of the high speed digital system 100 implementing the digital calibration device 140 with a half vernier TDC 205, according to one embodiment. It is noted that the half vernier TDC 205 is an exemplary embodiment of the timing device 125 of FIG. 1. In one example embodiment, the digital calibration device 140 calibrates the half vernier TDC 205 in the high speed digital system 100 for timing delays between the delayed line 275 and the non-delayed line 270 of the half vernier TDC 205.

The digital calibration device 140 includes a delay estimator 210, a control logic 215 and a digitally controlled load unit 220. The half vernier TDC 205 includes a plurality of first delay elements 235A-E, a second delay element 225, a third delay element 230, a first set of D-type flip-flops 240A-E, a second set of D-type flip-flops 245A-E, a first encoder 260 and a second encoder 265. In FIG. 2, the delay estimator 210 is coupled to the first output 130 and the second output 135 of the half vernier TDC 205. The control logic 215 is coupled to the delay estimator 210. The digitally controlled load unit 220 is coupled to the control logic 215. The non-delayed line 270 and the delayed line 275 are connected to the digitally controlled load unit 220 using the first load 145 and the second load 150, respectively.

At the core of the half vernier TDC 205 is a delay line which receives the first input signal 105 and includes the plurality of first delay elements 235A-E connected in series. The plurality of first delay elements 235A-E may include buffers, inverters, and the like. The output of each of the plurality of first delay elements 235A-E is sampled by two flip-flops. The first set of D-type flip-flops 240A-E receives the output of the plurality of first delay elements 235A-E at its respective data inputs; for instance, the output of the delay element 235A is received at the data input of the flip-flop 240A, the output of the delay element 235B is received at the data input of the flip-flop 240B, and so on. Accordingly, the second set of D-type flip-flops 245A-E receives the output of the plurality of first delay elements 235A-E at its respective data inputs; for instance, the output of the first delay element 235A is received at the data input of the flip-flop 245A, the output of the first delay element 235B is received at the data input of the flip-flop 245B, and so on. The outputs of the first set of flip-flops 240A-E are received by a first encoder 260, and the outputs of the second set of flip-flops 245A-E are received by a second encoder 265, as shown in FIG. 2.

Further, the second input signal 110 is received at the second delay element 225. The output of the second delay element 225 produced on the line 270 drives the clock inputs for the first set of flip-flops 240A-E. Also, the second input signal 110 is received at a third delay element 230. Similarly, the output of the third delay element 230 produced on the line 275 drives the clock inputs for the second set of flip-flops 245A-E. The amount of delay associated with the third delay element 230 is set at a predetermined value relative to the amount of delay associated with the second delay element 225. In the exemplary embodiment of FIG. 2, the amount of delay associated with the third delay element 230 is equal to 1.5 times the amount of the delay associated with the second delay element 225. For example, if the delay in the second delay element 225 is 2 picoseconds (ps), then the delay in the third delay element 230 is 3 ps. Therefore, the signal produced on the line 275 by the third delay element 230 is delayed with respect to the signal produced on the line 270 by the second delay element 225. Accordingly, the line 275 is referred to as the delayed line 275, and the line 270 is referred to as the non-delayed line 270.

When the second input signal 110 rises on the non-delayed line 270, some of the delayed clock inputs to the first set of flip-flops 240A-E are in a high state and others are in a low state. Accordingly, some of the outputs of the first set of flip-flops 240A-E are in a high state and outputs of remaining flip-flops are in a low state. Therefore, it is possible to detect the timing at which the second input signal 110 rises on the non-delayed line 270 by detecting the position at which the outputs of the first set of flip-flops 240A-E change using the first encoder 260. Similarly, when the second input signal 110 rises on the delayed line 275, some of the delayed clock inputs to the second set of flip-flops 245A-E are in a high state, while others are in a low state. Accordingly, some of the outputs of the second set of flip-flops 245A-E are in a high state and the outputs of remaining flip-flops are in a low state. Therefore, it is possible to detect the timing at which the second input signal 110 rises on the delayed line 275 by detecting the position at which the outputs of the second set of flip-flops 245A-E change using the second encoder 265.

Because the second set of flip-flops 245A-E receives its clock inputs at a delay shift from the clock inputs to the first set of flip-flops 240A-E, the second output 135 from the second encoder 265 is at a delay shift relative to the first output 130 from the first encoder 260. However, as with other vernier delay line schemes, fluctuations in the process, temperature, or voltage can lead to variations from the desired difference in a delay between the second delay element 225 and the third delay element 230, and thus the first output 130 and the second output 135. For example, the actual delay between the second delay element 225 and the third delay element 230 may be 1.2 ps, when the desired delay between the two is 1 ps, as shown in the previous example.

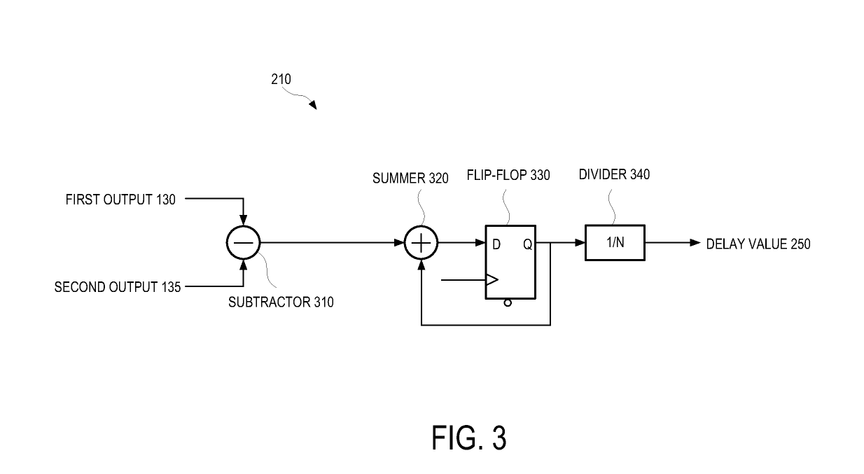

In an exemplary operation, the digital calibration device 140 uses the delay estimator 210 to calculate a delay value 250 that is indicative of a timing delay between the first output 130 of the first encoder 260 and the second output 135 of the second encoder 265. The timing delay can be defined as a delay in terms of time, phase, or any other measure. The delay value 250 can be calculated by the delay estimator 210 in several ways. One embodiment is to measure the difference in the data coming from the first output 130 and the second output 135 and then to calculate a timing delay using a physical circuit, as shown in FIG. 3. In another embodiment, the delay estimator 210 can be implemented in firmware as a software routine.

FIG. 3 illustrates a circuit diagram of the delay estimator 210 of the digital calibration device 140 of FIG. 2. In the physical circuit embodied in FIG. 3, the delay estimator 210 includes a subtractor 310, a summer 320, a D-type flip-flop 330, and a divider 340. The subtractor 310 produces the difference in timing delay between the first output 130 and the second output 135. The difference in timing delay is accumulated using the summer 320 and the D-type flip-flop 330 over a predetermined length of samples N, where N is an integer. The divider 340 receives the accumulated difference in timing delay and then divides the received accumulated difference in timing delay by value N, thus producing the calculated delay value 250.

In the exemplary embodiment, the amount of delay in the third delay element 230 is equal to 1.5 times the amount of delay in the second delay element 225; essentially, the amount of delay in the third delay element 230 is 0.5 times greater than the amount of delay in the second delay element 230. Therefore, the positions at which the outputs of the second set of flip-flops 245A-E change and the positions at which the outputs of the first set of flip-flops 240A-E change are equally likely to be the same or to differ by one position. Accordingly, over a length of time, the difference in timing delay is equal to zero for 50% of the time, and the difference in timing delay is equal to one for 50% of the time. Thus, in the exemplary embodiment, if the difference in timing delay is accumulated using the summer 320 and the D-type flip-flop 330 over the predetermined length of samples N, then the calculated delay value 250 would be equal to 0.5.

If the calculated delay value 250 is not equal to a desired predetermined value, then the first load 145 and the second load 150 is applied to the non-delayed line 270 and the delayed line 275, respectively. As in the embodiment shown in FIG. 2, the calculated delay value 250 is fed to the control logic 215, which determines whether to manipulate the delayed line 275 and/or the non-delayed line 270 using the digitally controlled load unit 220.

In the exemplary embodiment, if the calculated delay value 250 exceeds 0.5, the control logic 215 generates a control signal 255 that is received by the digitally controlled load unit 220. Based on the control signal 255 received, the digitally controlled load unit 220 may apply an increased load (e.g., the first load 145) on the non-delayed line 270 and/or apply a decreased load (e.g., the second load 150) on the delayed line 275. In comparison, if the calculated delay value 250 is less than 0.5, then the control logic 215 generates a control signal 255 that is received by the digitally controlled load unit 220. Based on the control signal 255 received, the digitally controlled load unit 220 may apply a decreased load (e.g., the first load 145) on the non-delayed line 270 and/or apply an increased load (e.g., the second load 150) on the delayed line 275. An increased or decreased load on a line may lead to a respective increased or decreased delay on the line.

The delay is then propagated into the appropriate set of flip-flops, where the digital calibration device 140 may apply the first load 145 and the second load 150 to the non-delayed line 270 and the delayed line 275, respectively, until a desired calculated delay value 250 is reached. In one embodiment, the control logic 215 is implemented in hardware. In another embodiment, the control logic 215 is implemented in firmware as a software routine. In some embodiments, the digitally controlled load unit 220 can be a number of elements, including a capacitor or resistor. In these embodiments, the first load 145 and the second load 150 applied to the non-delayed line 270 and the delayed line 275 may be a digitally controlled capacitive load or a digitally controlled resistive load.

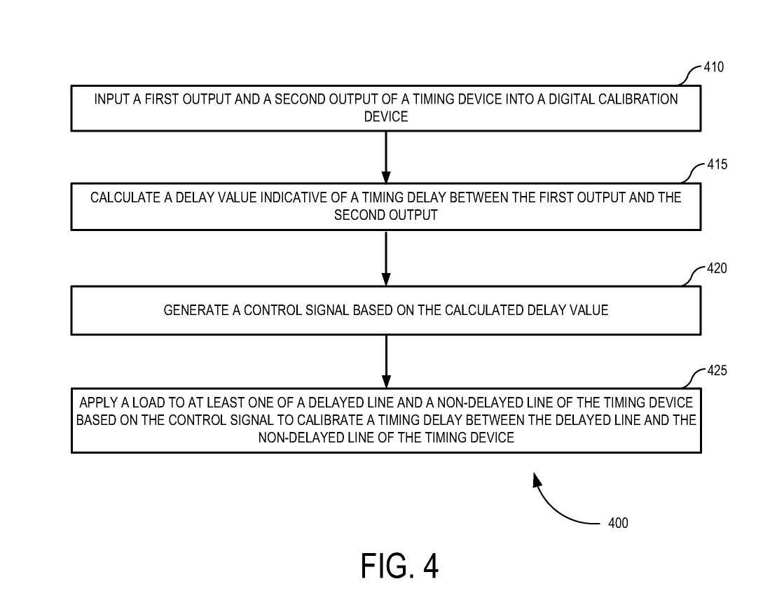

FIG. 4 illustrates a process flow chart of an exemplary method 400 of a digital calibration device for digitally calibrating a timing device of a high speed digital system, according to one embodiment. In operation 410, a first output and a second output from the timing device is inputted into the digital calibration device. For example, the first output and the second output are produced by processing a first input signal and a second input signal by the timing device. In operation 415, a delay value indicative of a timing delay between the first output and the second output of the timing device of the high speed digital system is calculated. For example, as illustrated in FIG. 2, the delay estimator 210 receives the first output 130 and the second output 135 and produces the delay value 250. An exemplary embodiment of the delay estimator 210 is shown in FIG. 3.

In operation 420, a control signal is generated based on the calculated delay value. For example, as illustrated in FIG. 2, if the calculated delay value 250 is greater than or less than 0.5, the control logic 215 generates the control signal 255 that is received by the digitally controlled load unit 220. In operation 425, a load is applied to at least one of a delayed line and a non-delayed line of the timing device based on the control signal to calibrate a timing delay between the delayed line and the non-delayed line of the timing device. For example, as illustrated in FIG. 2, based on the control signal 255 received, the digitally controlled load unit 220 applies the increased or decreased first load 145 to the non-delayed line 270 and/or the increased or decreased second load 150 to the delayed line 275, thereby calibrating a timing delay between the non-delayed line 270 and the delayed line 275.

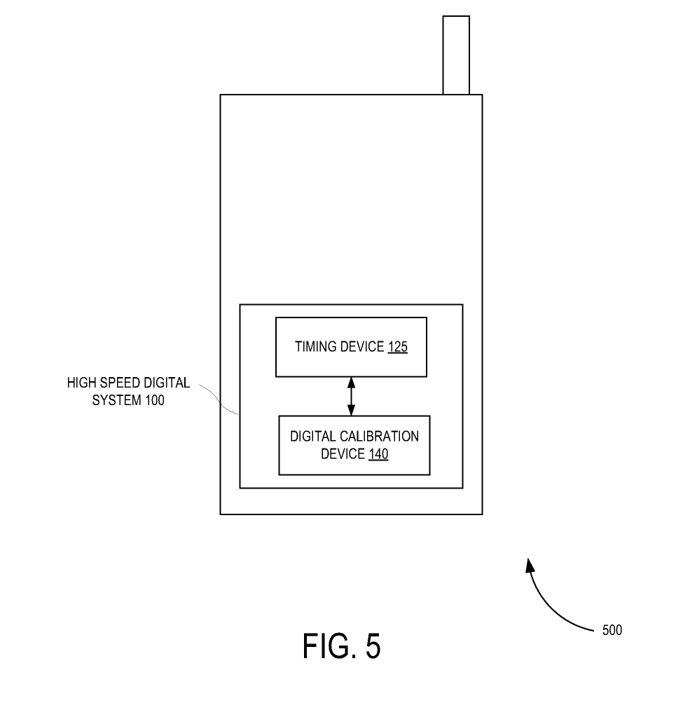

FIG. 5 illustrates an exemplary implementation of the high speed digital system 100 of FIG. 1 in a wireless device 500. The wireless device 500 includes the high speed digital system 100. The high speed digital system 100 includes the timing device 125 and the digital calibration device 140 for digitally calibrating the timing device 125. It is appreciated that the wireless device 500 can be any number of devices, including, but not limited to, wireless local area network (WLAN) devices, Bluetooth devices, and global positioning system (GPS) devices.

In various embodiments, the devices and methods described in FIGS. 1 through 5, facilitate significant reduction in complexity of designing a timing device, such as a half vernier TDC, due to their digital nature. Further, the above-described devices and methods allow the calibration to occur automatically on-chip using a firmware routine and spontaneously to compensate for changes in temperature and voltage; thus, it is unnecessary to use complex analog circuitry design.

The various devices, modules, analyzers, generators, etc. described herein may be enabled and operated using hardware circuitry (e.g., complementary metal-oxide-semiconductor (CMOS) based logic circuitry), firmware, software and/or any combination of hardware, firmware, and/or software (e.g., embodied in a machine readable medium). Further, the various electrical structure and methods may be embodied using transistors, logic gates, and/or electrical circuits (e.g., application specific integrated circuit (ASIC)). Although the present embodiments have been described with reference to specific example embodiments, it will be evident that various modifications and changes may be made to these embodiments without departing from the broader spirit and scope of the various embodiments. For example, the present embodiments are discussed in terms of a half vernier TDC. However, the present embodiments can be applied to various TDC designs, as well as other timing devices.

What is claimed is:

1. A digital calibration device for a high speed digital system, comprising:
a delay estimator for calculating a delay value indicative of a timing delay between a first output and a second output of a timing device of the high speed digital system;
a control logic for generating a control signal based on the delay value; and
a digitally controlled load unit for applying at least one of a first load to a non-delayed line and a second load to a delayed line of the timing device based on the control signal to calibrate a timing delay between the non-delayed line and the delayed line of the timing device.

2. The digital calibration device of claim 1, wherein the delay estimator calculates the delay value by averaging a difference in the timing delay between the first output and the second output of the timing device over a period of time.

3. The digital calibration device of claim 1, wherein the control logic generates the control signal when the delay value is not equal to a predetermined value.

4. The digital calibration device of claim 3, wherein the digitally controlled load unit increases or decreases the first load applied to the non-delayed line of the timing device based on the control signal.

5. The digital calibration device of claim 3, wherein the digitally controlled load unit increases or decreases the second load applied to the delayed line of the timing device based on the control signal.

6. The digital calibration device of claim 1, wherein the digitally controlled load unit applies a digitally controlled capacitive load to at least one of the non-delayed line using the first load and the delayed line using the second load based on the control signal.

7. The digital calibration device of claim 1, wherein the digitally controlled load unit applies a digitally controlled resistive load to at least one of the non-delayed line using the first load and the delayed line using the second load based on the control signal.

8. The digital calibration device of claim 2, wherein the delay estimator comprises:
a subtractor for calculating the difference in the timing delay between the first output and the second output of the timing device;
a summer for accumulating the difference in the timing delay over a predetermined length of samples N, where N is an integer; and
a divider for receiving the accumulated difference in the timing delay and dividing the received accumulated difference in the timing delay by a value N to calculate the delay value.

9. The digital calibration device of claim 1, wherein the timing device comprises:
a first delay line to receive the first input signal, wherein the first delay line has a plurality of first delay elements connected in series;
a second delay element to receive the second input signal, wherein the non-delayed line receives an output of the second delay element;
a third delay element to receive the second input signal, wherein the delayed line receives an output of the third delay element;
a first set of flip-flops with data inputs and clock inputs, wherein the first set of flip-flops are configured to receive outputs of the plurality of first delay elements at said data inputs and the non-delayed line at said clock inputs;
a second set of flip-flops with data inputs and clock inputs, wherein the second set of flip-flops are configured to receive outputs of the plurality of first delay elements at said data inputs and the delayed line at said clock inputs;
a first encoder to receive outputs from the first set of flip-flops and to produce the first output of the timing device; and
a second encoder to receive outputs from the second set of flip-flops and to produce the second output of the timing device.

10. A method for a digital calibration device to calibrate a timing device in a high speed digital system comprising:
calculating a delay value indicative of a timing delay between a first output and a second output of the timing device of the high speed digital system;
generating a control signal based on the delay value; and
applying at least one of a first load to a non-delayed line and a second load to a delayed line of the timing device based on the control signal to calibrate a timing delay between the non-delayed line and the delayed line of the timing device.

11. The method of claim 10, wherein calculating the delay value comprises:
calculating a difference in the timing delay between the first output and the second output of the timing device;
accumulating the difference in the timing delay over a predetermined length of samples N, where N is an integer; and
receiving the accumulated difference in the timing delay and dividing the received accumulated difference in the timing delay by a value N to calculate the delay value.

12. The method of claim 10, wherein generating the control signal comprises generating the control signal when the delay value is not equal to a predetermined value.

13. The method of claim 12, wherein applying at least one of the first load to the non-delayed line and the second load to the delayed line of the timing device comprises increasing or decreasing the first load applied to the non-delayed line of the timing device based on the control signal.

14. The method of claim 12, wherein applying at least one of the first load to the non-delayed line and the second load to the delayed line of the timing device comprises increasing or decreasing the second load applied to the delayed line of the timing device based on the control signal.

15. The method of claim 10, wherein applying at least one of the first load to the non-delayed line and the second load to the delayed line of the timing device comprises applying a digitally controlled capacitive load to at least one of the non-delayed line using the first load and the delayed line using the second load based on the control signal.

16. The method of claim 10, wherein applying at least one of the first load to the non-delayed line and the second load to the delayed line of the timing device comprises applying a digitally controlled resistive load to at least one of the non-delayed line using the first load and the delayed line using the second load based on the control signal.

17. A wireless device comprising:
a high speed digital system, comprising:
a timing circuit for receiving a first input signal and a second input signal and for providing a first output and a second output; and
a digital calibration circuit coupled to the timing circuit, comprising:
a delay estimator for calculating a delay value indicative of a timing delay between the first output and the second output of the timing circuit;
a control logic for generating a control signal based on the delay value; and
a digitally controlled load unit for applying at least one of a first load to a non-delayed line and a second load to a delayed line of the timing circuit based on the control signal to calibrate a timing delay between the non-delayed line and the delayed line of the timing circuit.
